(19) United States
(12) Patent Application Publication
(10) Pub. No.: US 2009/0168471 A1
(43) Pub. Date: Jul. 2, 2009

(54) CIRCUIT DEVICE HAVING A FREE WHEELING DIODE, CIRCUIT DEVICE AND POWER CONVERTER USING DIODES

(76) Inventors: Dai Tsugawa, Mito (JP); Katsumi Ishikawa, Hitachinaka (JP); Masahiro Nagasu, Hitachinaka (JP); Haruka Shimizu, Kodaira (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/342,361

(22) Filed: Dec. 23, 2008

(30) Foreign Application Priority Data
Dec. 26, 2007 (JP) 2007-333425

(51) Int. Cl. H02H 7/122

(52) U.S. Cl. 363/56.01

(57) ABSTRACT

A circuit device includes at least one switching element and a free wheeling diode connected in parallel to the switching element. The free wheeling diode is made up of a Schottky barrier diode using a semiconductor material having a band gap larger than silicon as its base material and also a silicon PiN diode, which are connected in parallel. The Schottky barrier diode and the silicon PiN diode are provided in the form of separate chips. A circuit system is also provided wherein a diode having a Schottky junction of a compound semiconductor as a rectification element built therein is combined, and a relationship, R²>4L/C, with impedance R (resistance), L (inductance), and C (capacitance) determined by a closed circuit between a power source and a positive or negative terminal when the current of the diode becomes zero during recovery operation, is satisfied.

### BACKGROUND OF THE INVENTION

The present invention relates to a circuit device having at least one switching element and at least one free wheeling diode connected in parallel with the switching element, a circuit and a circuit mounting system for a system of a power converter such as an inverter or a converter.

A semiconductor power module is used as a constituent element forming an inverter in a wide range of fields. In particular, a power module, using a Si-IGBT (Insulated Gate Bipolar Transistor) as a switching element and also using a Si-PiN diode (which will be referred to as the PND hereinafter) as a free wheeling diode, is high in breakdown voltage and low in loss. Such a power module is used in a wide range of fields including railroad and home appliances. In recent years, power saving becomes more important and the power module is required to further reduce its loss. The loss of the power module is determined by the performance of a power device. The performance of the Si-IGBT is made higher in these years, whereas the Si-PND cannot find its large breakthrough with the current state of the art. A current diode has a problem with such a recovery current as to cause carriers stored in the diode to be discharged when the IGBT is turned ON. The recovery current also involves another noise problem of increasing a switching loss. To avoid this, such a diode as to have a small recovery loss is strongly demanded. Since the characteristic of the Si-PND already reaches nearly such a high level as to be determined by the material physical properties, however, it is difficult to largely reduce the recovery current in the current state. As one of techniques for suppressing the recovery current in the past, there is suggested a technique which suppresses injection of minor carriers by providing a region having a Schottky interface in the anode-side surface of the PND. An example of a PND having a Schottky region is disclosed in U.S. Pat. No. 5,101,244A, Mori et al.

Meanwhile, a power element, using silicon carbide (SiC) as a base material and having excellent SiC physical characteristics, is expected to excel a Si power element. Since SiC has a large electric breakdown field strength, the SiC element can be made remarkably thinner than the Si element. For this reason, even in the case of a bipolar device, a high breakdown voltage and a low resistance when the device is conducted, can be simultaneously attained. Even in the case of the bipolar device, since the element can be made thin, the device can advantageously improve its switching characteristic with a less quantity of carriers stored in the device. Among SiC devices, a diode has a low ON resistance and a large capacitance when compared with a switching element. For this reason, an attempt has been made to reduce the loss of the device by combining the Si-IGBT and the SiC diode. An example of combinations between the Si-IGBT diode and the SiC diode is disclosed in U.S. Pat. No. 5,661,644A, Bergman et al.

Since the SiC diode unlike the Si diode can have a high breakdown voltage not lower than 3 kV even when the diode is a Schottky barrier diode (referred as the SBD hereinafter), the SiC diode can be selectively used as an SBD or a PND according to a breakdown voltage class. The SBD can have a diffusion potential smaller than the PND and also have a forward voltage upon conduction of a rated current lower than the PND, so that the PND is used in its low breakdown voltage range. Further, since the SBD is a unipolar device, the SBD can have a very small recovery current when the IGBT is turned ON. However, the recovery current becomes nearly zero, which results in that a current abruptly varies and this causes generation of switching nose based on the resonance between a capacitance component and an inductance component in the circuit. Noise may cause not only the destruction of the element but also a trouble in the entire system. Further, since a current larger than the PND cannot be passed through the SBD element, a momentary large current called a surge may cause the SBD to be destroyed. Meanwhile, the PND element having a high diffusion potential becomes high in forward voltage upon conduction of a rated current in its lower breakdown voltage range. However, since the PND is a bipolar device, the PND can have a voltage less increased by the thickness of a drift layer. Therefore, the PND can have a small forward voltage upon the conduction of the rated current in its high breakdown voltage range when compared with the SBD. In addition, since a large current can be passed through the PND, the PND can also have a high resistance to the surge. In this way, the SBD and the PND have their merits and demerits, and thus these elements are required to be selectively used depending on their applications.

As an element having two types of diodes combined, there is suggested an element which has an MPS (Merged PiN Schottky) structure. That is, the element has such a structure that has both a PN junction region and a Schottky junction region on the anode side. In a normal operational range of the element, the Schottky junction region is mainly operated. When a surge current flows through the element, the PN junction region is operated to protect the element. Upon reverse biased operation, a depletion layer is extended from the PN junction region to cause the Schottky junction region not to be exposed to a high electric field. Thus, a leakage current from the Schottky junction can advantageously be suppressed. An example of the MPS structures is disclosed in Proceedings of ISPSD2006, 305, entitled “2nd Generation SiC Schottky Diode: A new benchmark in SiC device ruggedness”.

A power converter is formed as an electric circuit including a switch and a rectifier.

A power converter such as an inverter or a converter is used for power conversion between DC and AC or for AC frequency conversion, and is employed in a large-capacity motor drive system or in a power system for electric power transmission or for power transformation.

As a converter element for use in the aforementioned system, a power semiconductor element such as a high-breakdown-voltage transistor or diode is employed in a large capacity application from the viewpoint of loss reduction.

In recent years, the IGBT (Insulated Gate Bipolar Transistor) is used as a voltage-controlled transistor element to attain high speed operation with a low loss. Meanwhile, as a diode, there has, so far, been employed a PN diode (PND) which has a rectification characteristic based on a junction between a P type semiconductor and an N type semiconductor. As the semiconductor material, silicon (Si) is generally used.

The PND using the conventional Si semiconductor has an advantage that a carrier storage effect caused by a PN junction or an effect of injecting two carriers of electrons and holes into the diode causes a resistance to drop and a current density to become large in a forward direction.

However, the PND also has a disadvantage that a reverse current causes generation of a (reverse bias) recovery loss. The reverse bias recovery loss becomes large in a high voltage current and a high voltage converter circuit has a problem with a diode loss and with heat generation caused by the loss.

When a diode including a Schottky junction is employed, on the other hand, the carrier storage effect becomes remarkably small upon conduction of the diode. For this reason, the diode has a merit that recovery operation is small and the reverse current is small. Thus, the diode has a merit that the loss of the diode upon switching operation becomes small.

It is known in these years that, when a compound semiconductor having a wide band gap such as silicon carbide (SiC) or gallium nitride (GaN) is used, the performances of the element can be made high even in an element having a high breakdown voltage, as when an integrated resistance of the diode can be made low and as when a current density can be made high.

When such a compound semiconductor having a wide band gap is used, a diode element, using a Schottky junction in a diode for use in a converter circuit having a high breakdown voltage of 200V or more, can be employed.

In a device including the MPS structure and also including only the SBD operated in a normal operation, however, noise is generated based on the aforementioned resonance between the capacitance and inductance components in the circuit. In order to suppress the noise, it is only required to pass a small amount of recovery current through the device to soften sluggish the switching operation (soft switching, zero volt switching or zero current switching). In the aforementioned MPS structure, however, the PND is not operated and substantially no recovery current flows through the PND in the normal operation range. As a result, the noise cannot be suppressed. The MPS structure has such a structure as shown in FIG. 9. The illustrated structure has both a PN junction region and a Schottky junction region on an anode side. An N⁺ type layer 14 having a high concentration and an N⁻ type drift layer 13 are laminated, and a plurality of P type impurity layers 12 and a P type termination layer 16 are formed in the N⁻ type drift layer 13. An anode electrode 10 is formed to the P type impurity layers 12 with a metal layer 11 disposed therebetween. In the drawing, an interface between the metal layer 11 and the N⁻ type drift layer 13 is a Schottky junction, and an interface between the P type impurity layers 12 and the N⁻ type drift layer 13 is a PN junction. A cathode electrode 15 is formed on the back surface of the high-concentration N⁺ type layer 14. Reference numeral 17 denotes an insulator layer.

Since the forward voltage of the PND becomes nearly the same as the forward voltage of the DBD even for the MPS structure in an application using a high breakdown voltage of 3 kV or more, two types of diodes are simultaneously operated, possibly enabling noise reduction. However, even when the aforementioned MPS structure is applied to the high-breakdown-voltage application as it is, a potential gradient is concentrated in a Schottky region and is not generated substantially in the vicinity of the PN junction region, thus involving a difficulty that even application of a voltage higher than a PN junction diffusion potential of the PND causes the PND not to be operated.

In view of the aforementioned technical background, the invention of this application is directed to reduce the conduction loss of an existing conversion circuit while suppressing noise in the conversion circuit.

In a converter circuit having a combination of a switching device and a diode connected in inverse parallel with the device, flowing of a recovery (reverse or reverse recovery) current through the diode causes voltages across input and output terminals or currents flowing therethrough to be varied. Since this causes excessive voltages to appear between the input or output terminals, thus disadvantageously possibly destroying the element. Variations in the diode voltage or current also cause noise to be generated in a peripheral circuit, thus disadvantageously involving erroneous operation of a peripheral device.

When a diode having a Schottky junction built therein such as an SBD is used as a rectification element, a loss during reverse recovery operation can be made small. It is known that employment of a diode having a Schottky junction of compound semiconductors having a large dielectric breakdown field such as SiC or GaN built therein enables remarkable reduction of the loss of a high-voltage diode.

However, use of a diode having a Schottky junction of compound semiconductors built therein may cause, in some cases, generation of oscillation waveforms of a high frequency voltage and current.

Such a phenomenon is caused by a phenomenon of resonance between the capacitance of the Schottky junction and the parasitic inductance of wiring formed in the power converter. This phenomenon may cause generation of a noise source to the peripheral circuit. Accordingly, as a target or object to be solved, it is required to reduce the oscillation upon reverse recovery operation of the diode as a noise source from the viewpoint of electromagnetic compatibility (EMC).

Largest one of features of the present invention is to arrange a free wheeling diode in a power module in such a manner that the SBD and the PND as separate chips are disposed in parallel. For the SBD, a semiconductor material having a band gap larger than a silicon material is used as its base material. For the PND, a silicon material or a semiconductor material having a band gap larger than the silicon is used as its base material. Major embodiments of the present invention are as follows.

(1) A circuit device including at least one switching element and a free wheeling diode which are connected in parallel thereto, wherein a Schottky barrier diode using a semiconductor material having a band gap larger than silicon as a base material and a silicon PiN diode are connected in parallel, and the Schottky barrier diode and the silicon PiN diode are provided in the form of separate chips.

(2) A circuit device including at least one switching element and a free wheeling diode connected in parallel thereto, wherein the free wheeling diode has a PiN diode and two or more Schottky barrier diodes connected in series, a semiconductor material having a band gap larger than silicon is used as a base material in the Schottky barrier diode, a semiconductor material having a band gap larger than silicon is used as a base material in the PiN diode, and the Schottky barrier diode and the PiN diode are provided in the form of separate chips.

(3) A circuit device set forth in the above paragraph (1) wherein the semiconductor material having a band gap larger than silicon is made of silicon carbide (SiC) or gallium nitride (GaN).

(4) A circuit device set forth in the above paragraph (2) wherein the semiconductor material having a band gap larger than silicon to form the Schottky barrier diode and the PiN diode is made of silicon carbide (SiC) or gallium nitride (GaN).

(5) A circuit device set forth in the above paragraph (1) wherein the Schottky barrier diodes are provided in the form of a plurality of separate Schottky barrier diode chips arranged in parallel, and the number of such PiN diodes is smaller than the number of such Schottky barrier diode chips.

(6) A circuit device set forth in the above paragraph (1) wherein a junction surface area of the PiN diode is smaller than a junction surface area of the Schottky barrier diode.

(7) A circuit device set forth in the above paragraph (1) or (2) wherein the Schottky barrier diode is a junction barrier Schottky diode.

The gist of the present invention has been explained. In accordance with the present invention, since the SBD and the PND as separate chips are connected in parallel, an equal voltage is applied to each diode so that the respective diodes are operated independently of each other. Since the circuit device is used in the vicinity of a current range where the forward voltage of the SBD is equal to the forward voltage of the PND, the circuit device can reduce noise while maintaining the excellent recovery characteristic of the SBD.

The above problems can be solved by providing a circuit system which has a combination of a switching element, passive elements, and a diode having a built-in Schottky junction of a compound semiconductor material (having a high dielectric breakdown field) as a rectification element and which satisfies a relationship with impedance R, L and C determined by a closed circuit between a power source and a positive or negative terminal upon recovery operation when the current of the diode becomes zero, which follows.

R²>4L/C (1)

In accordance with the present invention, noise in an existing conversion circuit can be reduced.

In accordance with the present invention, a circuit constant among a power source, a switching element, a diode, and wiring lines connected thereto establishes non-resonance conditions at the time moment at least when the backflow current becomes zero. With it, a oscillation current when the recovery current flows in the diode can be reduced, and thus both a loss and noise can also be reduced.

As a result, there can be provided an electric circuit system for a power converter which achieves compatibility between the loss reduction and the noise reduction, and also provided a converter system for implementing the circuit system.

Other objects, features and advantages of the invention will become apparent from the following description of the embodiments of the invention taken in conjunction with the accompanying drawings.

### BRIEF DESCRIPTION OF THE DRAWINGS

FIG. 1 shows a circuit diagram of a module in accordance with a first embodiment of the present invention;

FIG. 2 shows a perspective view of the module in accordance with the first embodiment of the present invention;

FIG. 3 shows a current/voltage characteristic diagram of the module in accordance with the first embodiment of the present invention;

FIG. 4 is a diagram for explaining the effect of the module in accordance with the first embodiment of the present invention;

FIG. 5 shows part of a circuit diagram of a module in accordance with a modification of the first embodiment of the present invention;

FIG. 6 shows a perspective view of the module in accordance with the modification of the first embodiment of the present invention;

FIG. 7 shows part of a circuit diagram of a module in accordance with a second embodiment of the present invention;

FIG. 8 shows a current/voltage characteristic diagram of the module in accordance with the second embodiment of the present invention;

FIG. 9 shows a cross-sectional view of a typical MPS structure;

FIG. 10 is a circuit diagram for explaining a third embodiment of the present invention;

FIG. 11 is a circuit diagram for explaining a fourth embodiment of the present invention;

FIG. 12 is a circuit diagram for explaining a fifth embodiment of the present invention;

FIG. 13 is a circuit diagram for explaining a sixth embodiment of the present invention;

FIG. 14 is a circuit diagram for explaining a seventh embodiment of the present invention;

FIG. 15 is a circuit diagram for explaining a eighth embodiment of the present invention;

FIG. 16 is a circuit diagram for explaining a ninth embodiment of the present invention;

FIG. 17 is a circuit diagram for explaining a tenth embodiment of the present invention;

FIG. 18 is a circuit diagram for explaining a eleventh embodiment of the present invention; and

FIG. 19 is a circuit diagram for explaining a twelfth embodiment of the present invention.

### DESCRIPTION OF THE EMBODIMENTS

Embodiments of the present invention will be explained with reference to the accompanying drawings.

### 1. First Embodiment

Explanation will first be made as to the first embodiment. The present embodiment is directed to a circuit device which includes at least one switching element and at least one free wheeling diode connected in parallel thereto, wherein a Schottky barrier diode and a silicon PiN diode having a semiconductor material with a band gap larger than silicon as a base material are connected in parallel, and the Schottky barrier diode and the silicon PiN diode are provided in the form of separate chips. The semiconductor material having a band gap larger than silicon is made of silicon carbide (SiC) as a typical example. The semiconductor material may also be made of gallium nitride (GaN). The free wheeling diode plays a role of holding a characteristic voltage and passing a current necessary for a load when the switching element is turned OFF by smoothing an abrupt variation in a circuit caused by the switching operation of the switching element, that is, plays a role of protecting the switching element.

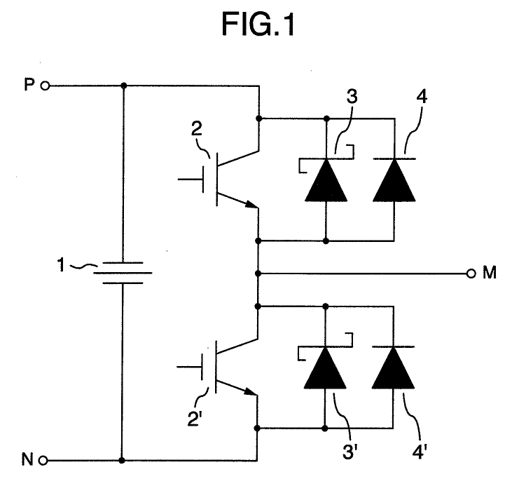

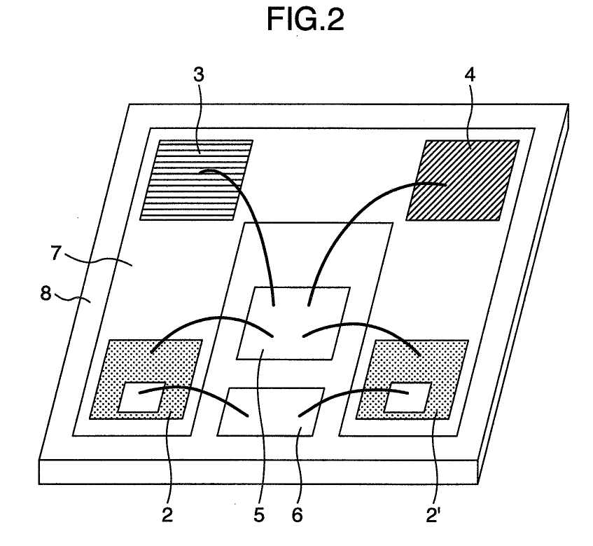

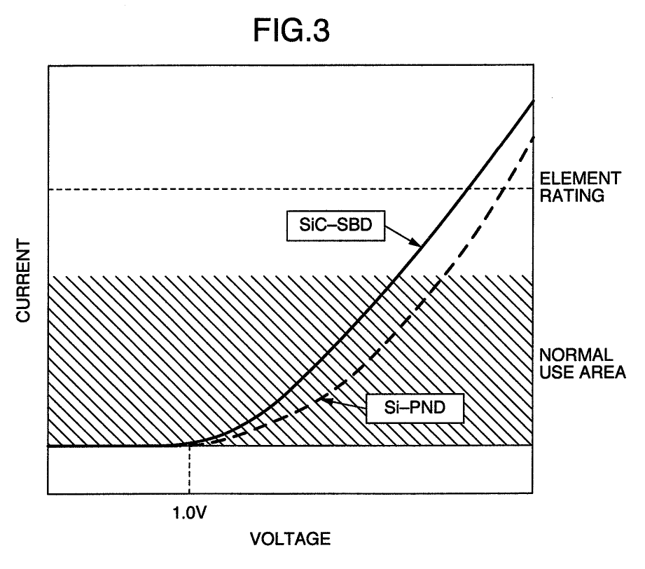

FIG. 1 is a first embodiment of the present invention, showing a major part of a circuit diagram when a power module is used as an inverter circuit. FIG. 2 is a perspective view of part of the power module. A switching element Si-IGBT 2 and a switching element Si-IGBT 2′ in FIG. 2 correspond to IGBTs 2 and 2′ respectively in FIG. 1. In the power module, a SiC-SBD 3 and a Si-PND 4 are connected in parallel to the Si-IGBT 2. Both ends of the Si-IGBT 2 are connected to a power source of the inverter circuit. The constituent elements of the inverter circuit are arranged as exemplified in FIG. 2. However, FIG. 3 shows not the entirety of the circuit but only part thereof. Reference numerals or symbols in FIG. 2 are the same as those in FIG. 1. Reference numeral 5 denotes an emitter terminal, numeral 6 denotes a gate terminal, and 7 denotes a collector terminal.

The operation of the present embodiment will be briefly explained. In a 3-phase inverter circuit, the two IGBTs (2 and 2′) connected in series are connected in parallel to 3-phase lines. When a total of 6 IGBTs are sequentially turned ON and OFF, a DC current can be converted to a desired AC current. The diodes (Schottky barrier diodes 3, 3′ and PiN diodes 4, 4′) connected in parallel to the IGBT play a role of supplying a current necessary when the IGBT is turned OFF. For example, when the IGBT 2 is turned OFF, a current so far flowing through a load flows through a Schottky barrier diode 3′ and a PiN diode 4′ connected in parallel to the IGBT 2′. At this time, a ratio between currents flowing through the respective diodes is determined by a ratio in surface area between the diodes and by static characteristics thereof. When the IGBT 2′ is turned OFF in this state, on the other hand, currents so far flowing through the Schottky barrier diode 3′ and the PiN diode 4′ are stopped, and carriers stored in the diodes flow in a reverse direction as recovery currents. The recovery currents become a cause of increasing a switching loss, but also function as a damper, that is, play another role of suppressing noise caused by the resonance of the circuit.

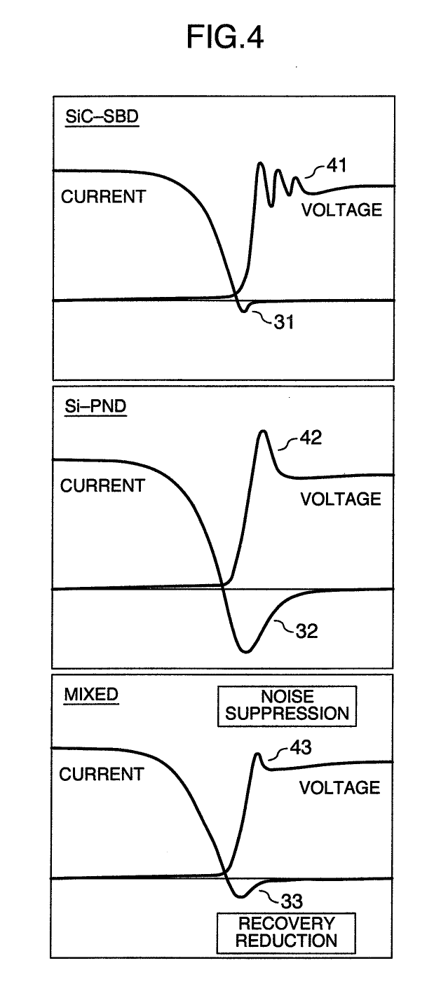

A combination of the SiC-SBD with the Si PND generates advantages which follow. Since the Si-PND has a recovery current larger than the SiC-PND, noise can be suppressed only by mixedly mounting the Si-PND having a small surface area. FIG. 3 is a static characteristic diagram of the SiC-SBD and the Si-PND for comparison therebetween. The drawing shows an example of an element rating and a normal use area (hatched area). Use of the Si-PND is featured in that, the static characteristic of the SiC-SBD is similar to that of the Si-PND as shown in FIG. 4, so that a ratio between currents flowing through the SiC-SBD and the Si-PND can be made nearly constant even in any of the current range. For this reason, the ratio between currents flowing though the SiC-SBD and the Si-PND can be made optimum at all times, with the result that a trade-off between noise and recovery can be effectively improved. In the present embodiment, since the static characteristic of the SiC-SBD is comparatively close to the static characteristic of the Si-PND even for any of breakdown voltage classes, the present embodiment is effective regardless of the breakdown voltage classes. In the present embodiment, each device is set to have a breakdown voltage of 4.5 kV as an example.

Explanation will then be made as to a specific characteristic example. FIG. 4 shows recovery characteristics for comparison when the inverter circuit is made up of only the SiC-SBDs, when the inverter circuit is made up of only the Si-PNDs, and when the inverter circuit is made up of the SiC-SBD and the Si-PND mixedly. In the drawing, the respective cases are denoted by ‘SiC-SBD’, ‘Si-PND’ and ‘Hybrid or Mixed’. In each of the static characteristic diagrams, an abscissa axis denotes time and an ordinate axis denotes current or voltage. In the case of ‘SBD’, a recovery current 31 is very small, but the resonance between capacitance and inductance components in the circuit causes generation of noise 41. In the case of only the PNDs, a recovery current 32 is large but this causes no generation of noise 42 because of the soft switching. When the SiC-SBD and the Si-PND are mixedly mounted, a recovery current 33 is at an intermediate level between the recovery current of the SBD and the recovery current of the PND, but this causes no generation of noise 43 because of the operation of the PND.

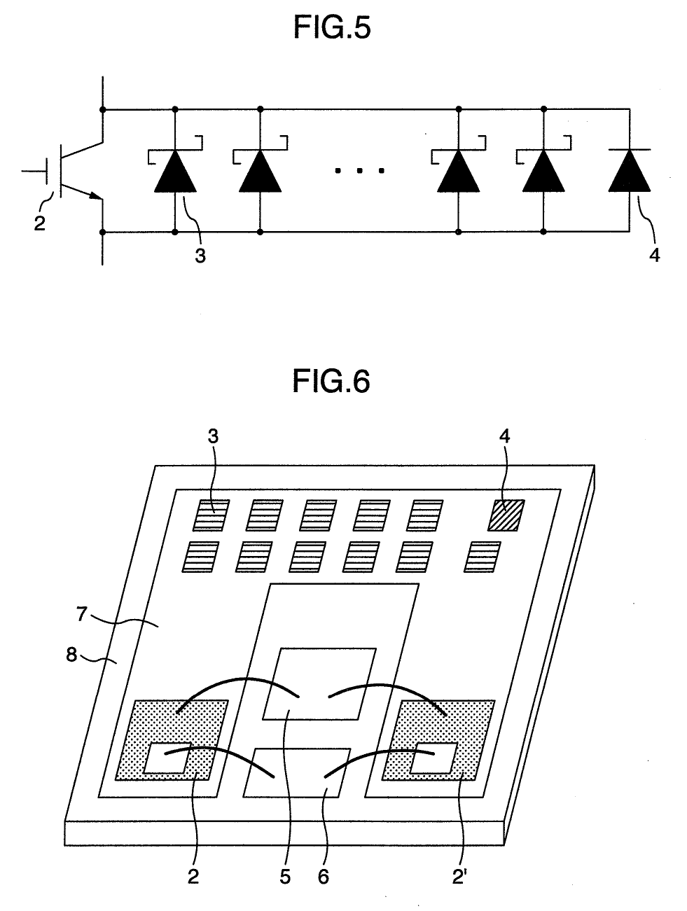

It is desirable that the surface area of the Schottky junction be larger than the surface area of the PN junction in the mixed diode circuit. This is because most of the recovery current is made advantageously to flow through the SBD from the viewpoint of loss and because the recovery current of the SBD is smaller than the recovery current of the PND. Thus it is only required to mixedly mount the SBD and the PND only on a minimum area for noise reduction. The ratio of the PND necessary to reduce noise varies with the inductance of the circuit or the like. However, noise can be reduced with generally a half or less of the current flowing through the PND. As a means for changing the surface area ratio, it is valid not to change the surface area of each chip but to change the number of chips as shown in FIGS. 5 and 6. This easily enables change of the surface area ratio.

In the present embodiment, the SBD and the PND are mixedly provided as separate chips. As mentioned previously, this is because the PND cannot be normally operated even when an MPS structure having a breakdown voltage of 3.3 kV or more is formed. Even when the SBD and the PND are arranged in the same chip, the PND can be normally operated in the vicinity of a center of the PND when it has a sufficiently broad PN junction region, but cannot be operated in the periphery thereof. Meanwhile, when the SBD and the PND are provided in the form of separate chips, the diode can be normally operated throughout the entire active range. As a result, not only the embodiment can have no surface area loss but the embodiment can also simplify its process and increase a yield. There exists many basal plane dislocations in a SiO substrate which are considered to adversely affect a PN junction. Thus the PND having a PN junction has a yield lower than the SBD. For this reason, a total yield can be increased and a cost can be reduced, rather by providing the SBD and the PND in the form of separate chips and then combining these chips, than by forming the SBD and the PND in the same chip. Even when the quality of the substrate is improved, formation of the junction by ion implantation in the PND possibly involves a defect therein and the PND does not work normally, and exhibiting effects similar to the above case.

The first embodiment corresponds to a combination of the SiC-SBD and the SiC-PND. However, the SBD may be replaced with a junction barrier Schottky diode (JBS). The JBS is a device of a structure having a P region on the surface of the SBD and of a type protecting a Schottky interface with a depletion layer extended from a PN junction in a reverse bias mode. The JBS is different from the MPS in that no ohmic contact is provided to the P region and the PN junction region does not act as a diode. The JBS has a forward characteristic similar to the SBD and can be applied even to the present embodiment.

### 2. Second Embodiment

A second embodiment will next be explained.

The present embodiment is directed, as an example, to a circuit device which includes at least one switching element and a free wheeling diode connected in parallel to the switching element, wherein the free wheeling diode is made up of a Schottky barrier diode having a base material with a band gap larger than silicon and two or more PiN diodes connected in series therewith, the PiN diode uses a semiconductor material having a band gap larger than silicon as its base material, and the Schottky barrier diode and the PiN diode are provided in the form of separate chips.

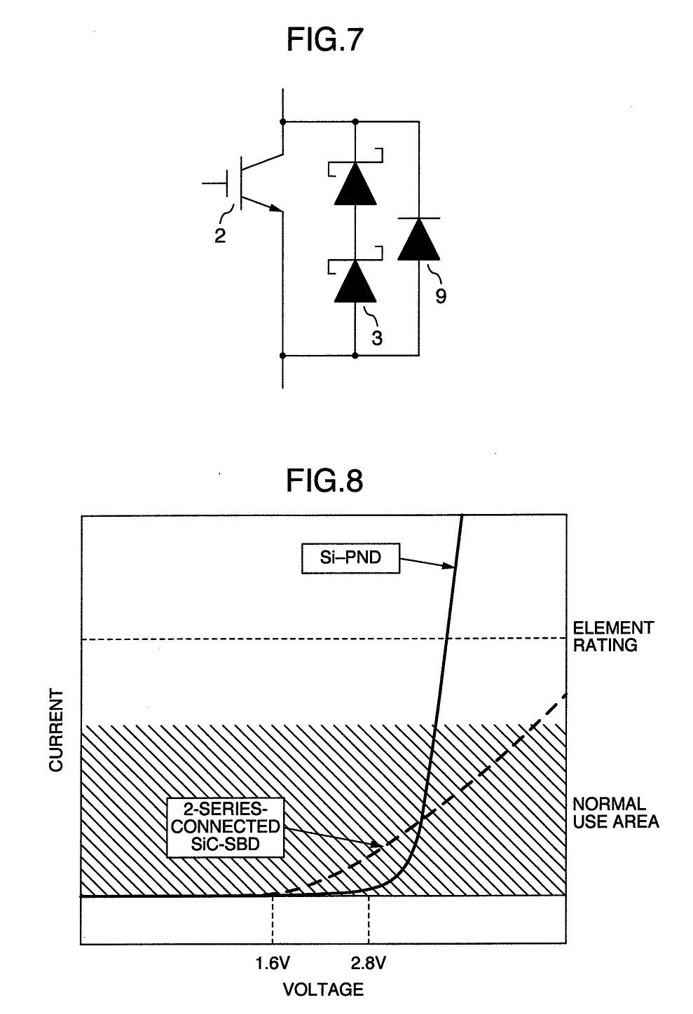

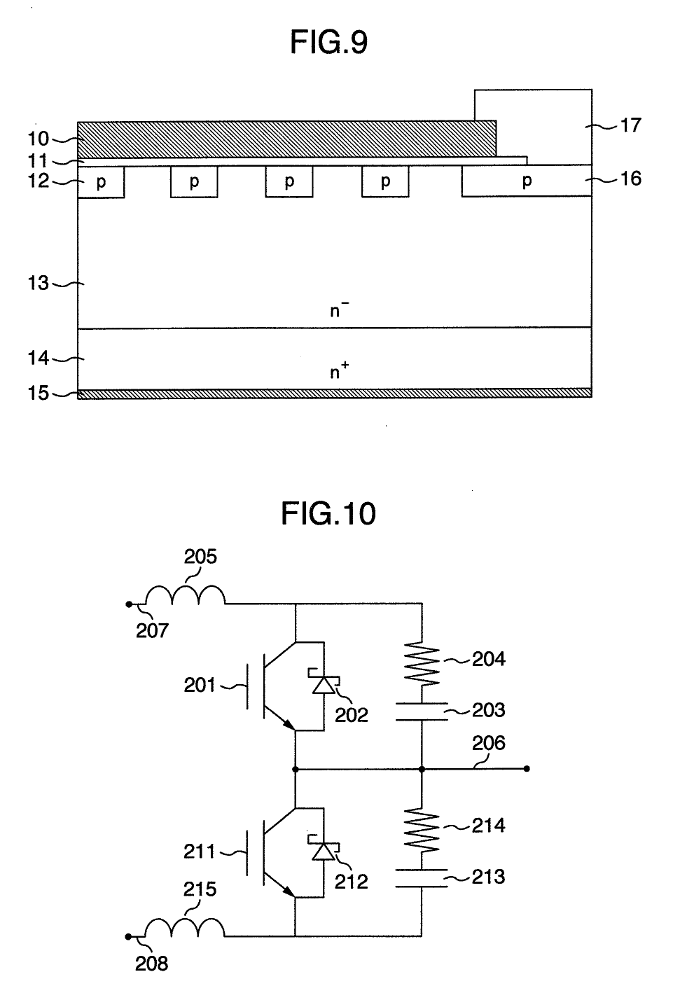

FIG. 7 shows part of an inverter circuit to which a power module is applied in the second embodiment. FIG. 7 is different from the example of FIG. 1 in two first and second respects, that is, in that (1), as the first respect, a PiN diode made of a semiconductor material having a band gap larger than silicon is used in place of the PiN diode made of a silicon semiconductor, and that (2), as the second respect, such Schottky barrier diodes are used to be connected in series. A typical example of the semiconductor material having a band gap larger than silicon is silicon carbide (SiC). The semiconductor material can also be a gallium nitride (GaN). FIG. 8 shows an example of a voltage/current characteristic of the present embodiment. In the drawing, a curve shown by a solid line is a characteristic of the SiC-PND, and a curve shown by a dotted line is a characteristic of two SiC-SBDs connected in series. The SiC-PND is usually largely different in static characteristic from the SiC-SBD, and the two diodes are seldom operated simultaneously in a normal operational range. However, when two of the SiC-SBDs are connected in series to increase a current rising voltage, this causes generation of a range where the two diodes are simultaneously operated. This enables the recovery current of the SiC-PND to suppress noise and also enables the mixed mounting of the SiC-SBD to reduce a total recovery current as in the first embodiment, thus suppressing a loss.

In the foregoing embodiment, the switching device may be a device other than the Si-IGBT, such as a Si-GTO (Gate Turn on Thyristor), a SiC-MOSFET (Metal-Oxide-Semiconductor Field Effect Transistor) or a SiC-JFET (Junction Field Effect Transistor).

The present invention relates to a circuit device or a circuit module which includes at least one switching element and also includes a diode conducted when the switching element is turned OFF and reversely biased when the switching element is turned ON. The present invention is highly useful when applied, in particular, to various types of converters including an inverter, a rectifier or a DC converter for DC/AC conversion.

### 3. Third Embodiment

The arrangement of a converter circuit in accordance with a third embodiment of the present invention will be explained by referring to the drawings.

FIG. 10 shows a basic circuit in the arrangement of the converter circuit of the present invention. In FIG. 10, the basic circuit includes a first switching element 201, a first Schottky diode 202, a first capacitance 203, a first resistance 204, a positive side inductance 205, an AC terminal 206, a circuit positive terminal 207, a circuit negative terminal 208, a switching element 211 for the first Schottky diode 202, a second Schottky diode 212, a second capacitance 213, a second resistance 214, and a negative side inductance 215.

The circuit of the present embodiment will be explained with reference to FIG. 10.

FIG. 10 shows a basic circuit of a combination of the diodes and the switching elements forming the converter circuit. A combination of such basic circuits is used as a converter circuit such as an inverter, a converter or a buck-boost chopper.

In the present invention, a Schottky diode (SBD) made of a compound semiconductor is used as the diode 202; simultaneously the capacitance 203, the first capacitance C 203, the first resistance (R) 204, and the inductance (L) 205 are adjusted to form the basic circuit as shown in FIG. 10; and such a basic circuit is considered to be applied to a converter circuit.

The effects of the present invention will be explained by comparing it with the effects of a DC/AC converter circuit.

In an inverter circuit including a usual switching element and a diode connected in inverse parallel to the switching element, a oscillation current is generated when the recovery current flows in the diode. This phenomenon is caused by circuit constants including a parasitic inductance Ls or a parasitic resistance Rs between the positive and negative terminals provided outside of the circuit or provided to a power source in the diode recovery mode, an ON resistance Ron of the on-side switching element, a parasitic resistance Rd, and a parasitic capacitance Cs of the diode.

When one switching element is turned ON, a forward current so far flowing between the diode not connected in parallel to the turned-ON switching element and a load becomes small and eventually zero. Directly after the forward current becomes zero, a reverse bias is applied to the above diode. The diode has a rectifying function and no reverse current ideally flows through the diode. In actuality, however, a reverse current flows through the diode during a charging time of a diode parasitic capacitance Cj in a reverse bias mode. At this time moment, a resonance phenomenon takes place and a oscillation current is generated.

The resonance conditions at this time moment are determined according to a discriminant (2) with circuit constants which follows.

D=Ron²−4Ls/Cj (2)

Wherein, as the circuit constants, Ron denotes a resistance component of a power supply circuit and the turned-ON switching element which transiently varies, Cj denotes a parasitic capacitance of the diode not connected in parallel to the turned-ON switching element, and Ls denotes a parasitic inductance of the circuit.

When D≦0 is satisfied, the converter circuit is of a resonance type. When D>0 is satisfied, the converter circuit is of a non-resonance type. In other words, in order to prevent generation of the oscillation current in the recovery operation leading to noise generation, it is necessary for D in the discriminant expressed by the internal impedance of the converter circuit to have a positive value.

In the prior art circuit system, when the resonance conditions, D<0, are satisfied, a current or voltage oscillation in the recovery operation is resonated in the converter circuit, which results in noise generation.

In the present embodiment, the first capacitance Cs is connected in parallel to the diode parasitic capacitance Cj not connected in parallel to the turned-ON switching element. This causes the capacitance component of the discriminant (2) in a closed circuit which determines the resonance conditions to be increased by an amount corresponding to the first capacitance Cs. That is, D in the above discriminant is expressed as follows.

D=Ron²−4Ls/(Cj+Cs) (3)

As a result, there can be provided a circuit which satisfies non-resonance conditions when such a capacitance Cs as to cause D in the discriminant with a transient impedance at the time moment of generation of the oscillation current caused by the diode recovery to have a positive value, is connected in parallel to the recovering diode. Accordingly, because the increased capacitance enables suppression of the oscillation current caused by the diode recovery, a converter circuit with low noise can be provided.

The first resistance Rs 204 connected in series with the first capacitance Cs 203 and in parallel to the diode 202 in FIG. 10 has a function of suppressing voltage oscillation during the recovery operation. In the diode recovery operation, a reverse current is generated in the diode and a reverse voltage is also generated in the diode. Since a time change rate in the voltage can be controlled by a time constant determined by the first capacitance Cs and the first resistance Rs, insertion of a suitable value of the resistance Rs can advantageously suppress noise in the converter.

When compared with a converter using the same voltage, a loss of the prior art Si-PND can be made small by using a Schottky diode of a compound semiconductor as the diode 202.

Therefore, in accordance with the present embodiment, there can be provided an electric circuit and a converter which can attain the above object.

In the present embodiment, the load circuit has been shown for the recovery of the first Schottky diode when the second switching element is turned ON. However, it is obvious, even in the recovery phenomenon of the second Schottky diode generated when the first switching element is turned ON, that optimization of the second capacitance and the second resistance can provide similar characteristics and noise reduction based thereon.

### 4. Fourth Embodiment

FIG. 11 shows a fourth embodiment of the present invention. In FIG. 11, the same constituent elements as those in FIG. 10 are denoted the same reference numerals. FIG. 11 is different from FIG. 10 in that the capacitances and the resistances connected in parallel to the first and second diodes are replaced with oscillation suppressing diodes 209 and 210 respectively.

The effects of the present embodiment will be explained. The diode is equivalent to a variable capacitance and a variable resistance connected in series when the capacitance Cs and the resistance Rs vary with the switching operation of the diode. For this reason, as has been explained in the first embodiment, when the impedances of the first and second diodes are adjusted so that the internal impedance of the circuit satisfies the discriminant (2) at the moment of recovery occurrence, there can be provided a converter circuit which attains the above object.

When the impedance of the oscillation suppressing diodes is adjusted so that D in the discriminant (2) has a positive value at the moment of the recovery of the diode as in the first embodiment, the oscillation current can be suppressed during the diode recovery operation. When the resistance component Rd and the capacitance component Cd are added in the oscillation suppressing diode unlike the first embodiment, the combined impedance of the entire circuit in the switching mode transiently varies. For example, when the oscillation suppressing diode is an PND, the resistance component Rd and the capacitance component Cd in the switching mode are varied by the transient phenomenon in the switching mode. Therefore, in a closed circuit including the diodes, the turned-ON switching element, and an accessory component; when the transient impedance at the moment of the diode recovery operation is optimized so as to satisfy the relationship (1), the above object can be attained and the effects of the present invention can be obtained. When the capacitance and the resistance are replaced with the oscillation suppressing diode, the number of components necessary in the circuit can be reduced. As a result, combined effects including the reduced number of necessary components in the entire circuit or simplification of circuit mounting can be expected.

In this connection, the oscillation suppressing diode can be made of not only the compound semiconductor but also a known Si semiconductor or the like.

### 5. Fifth Embodiment

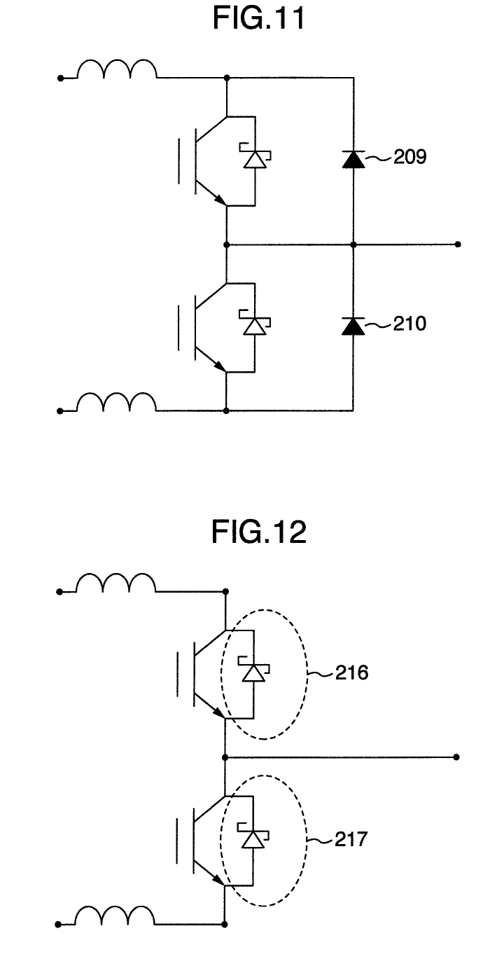

FIG. 12 shows a fifth embodiment of the present invention. In FIG. 12, the same constituent elements as those in FIG. 10 are denoted by the same reference numerals. FIG. 12 is different from FIG. 10 in that the a first composite diode 216 and a second composite diode 217 having each a Schottky junction and a PN junction are provided. When the PN junction is built in the interior of the diode, a forward current characteristic can be improved. At the moment of the diode recovery, the initial quantity of electric charge when the voltage and current oscillation caused by the recovery starts, becomes large, thus increasing the oscillation. In order to suppress the oscillation, as shown in the first and second embodiments, elements such as the oscillation suppressing capacitance and resistance are provided to be connected in parallel to the recovering diode. Thus, when the diode is designed so that the conditions shown by the relationship (1) are transiently satisfied, the effects of the present invention can be achieved.

### 6. Sixth Embodiment

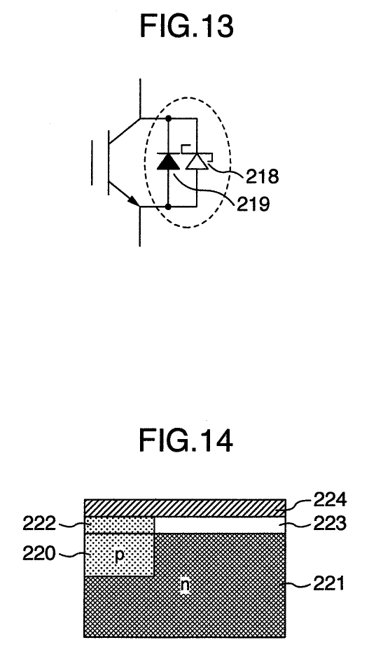

FIG. 13 shows a sixth embodiment of the present invention. FIG. 13 shows an equivalent circuit of a built-in diode in FIG. 12. A PN diode part 219 is provided to be connected in parallel to a Schottky diode part 218. The parallel configuration of the diodes 218 and 219 in the circuit enables the effects of the present invention to be attained.

### 7. Seventh Embodiment

FIG. 14 shows a seventh embodiment of the present invention. FIG. 14 shows a cross-sectional view of a composite diode in FIG. 12 in the vicinity of an anode electrode. Explanation will be made in connection with FIG. 14. Shown in FIG. 14 are a p-doped region 220, an n-doped region 221, an ohmic contact 222, a Schottky contact 223, and a metal electrode 224. An actual diode has such a structure that the above structure is repeated. The metal electrode 224 is used as an anode electrode. The metal electrode 224 is contacted with two semiconductor regions of the region 220 having a p type impurity doped therein and the region 221 having an n type impurities doped therein. This causes the ohmic contact 222 to be formed as a p type semiconductor part and also causes the Schottky contact 223 to be formed as an n type semiconductor part. As a result, a PN diode and a Schottky diode can be formed in the same chip. In this case, in order to suppress the oscillation current when the diode is used, impurity concentrations in the p-doped region 220 and the n-doped region 221 are optimized. Therefore, there can be provided a converter circuit and a power converter system in which the impedance of interior of the diode satisfies the relationship (1).

### 8. Eighth Embodiment

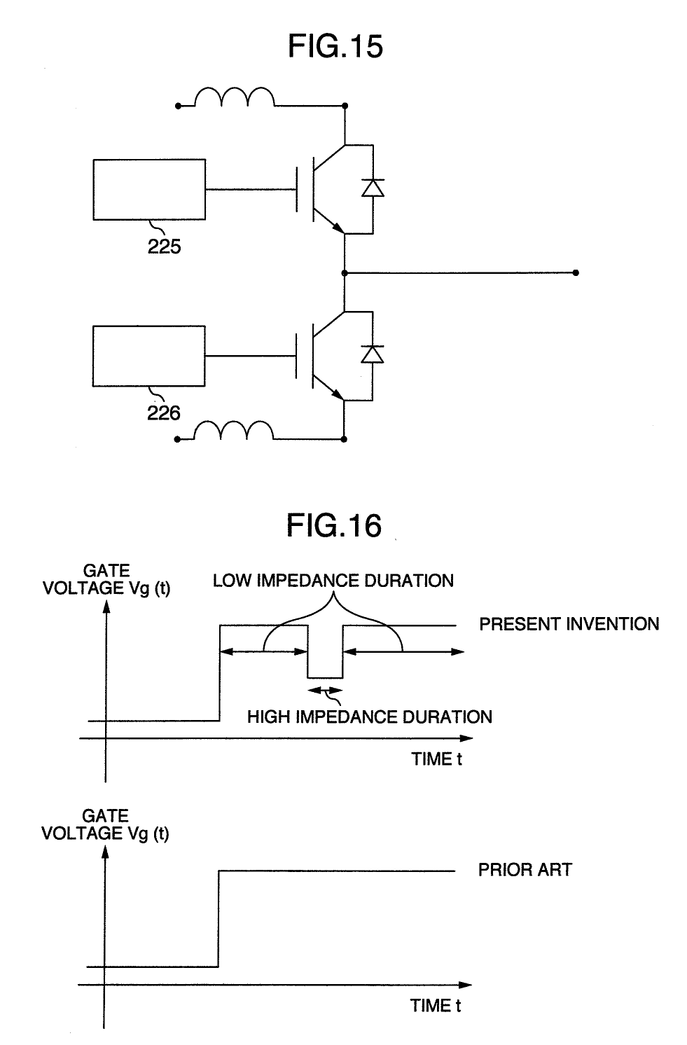

FIG. 15 shows an eighth embodiment of the present invention. FIG. 15 is a converter circuit having an arrangement similar to FIG. 12. Shown in FIG. 15 are a first gate terminal 225 and a second gate terminal 226. Application of an ON signal to the gate terminal causes the switching element to be turned ON. When the switching element turns ON, the recovery current flows in the diode. Resonance conditions of the recovery current flowing through the diode can be expressed by the discriminant (2). That is, when the ON resistance Ron is transiently increased from zero to a reverse flowing level, conditions similar to the relationship (1) can be obtained. With it, the effects of the present invention can be achieved.

As an embodiment suitable to implement such a circuit, when the gate signal level of the switching element is decreased as shown in FIG. 13, the ON resistance Ron is transiently increased at the moment of the recovery, so that such conditions as to satisfy the relationship (1) can be transiently created. Accordingly, the oscillation current can be suppressed, and the effects of the present invention can be achieved.

### 9. Ninth Embodiment

FIG. 16 shows a ninth embodiment of the present invention. FIG. 16 is a time chart of a gate signal pulse when the ON resistance Ron in the sixth embodiment is transiently increased. When the switching element is an IGBT, the transient impedance of the IGBT can be varied by controlling the gate voltage. FIG. 16 is a diagram for explaining a difference in waveform between a voltage command signal in the prior art as shown in the lower part of FIG. 16 and a voltage command signal as shown in the upper part of FIG. 16 to turn ON the IGBT, for comparison.

When the IGBT so far turned OFF is turned ON, a positive voltage is applied to the gate. Thus, a positive voltage is applied from the gate voltage at its OFF level to turn ON the switching element. For this reason, such a rectangular pulse as shown by the lower part in FIG. 16 is applied.

When it is desired to control the transient impedance as shown in the sixth embodiment, the impedance during turn-ON period can be controlled by changing the voltage level of a gate voltage Vg(t) in the case of the IGBT. As shown by the upper part in FIG. 16, a turn-ON pulse is applied to provide a high impedance period when the IGBT is turned ON. During this period, such conditions as to meet the relationship (1) are established at the time moment when the recovery current flows in the diode which is not connected in parallel to the IGBT.

### 10. Tenth Embodiment

An embodiment for implementing the present invention in the form of a converter will be explained.

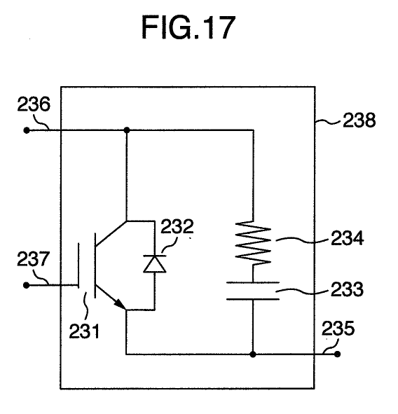

FIG. 17 shows a tenth embodiment of the present invention. FIG. 17 shows a relationship between a basic circuit of a converter having an arrangement similar to FIG. 12 and a module casing. The basic circuit includes a switching element 231, a diode 232, a oscillation suppressing capacitance 233, ant oscillation suppressing resistance 234, an emitter terminal 235, a collector terminal 236, a gate terminal 237, and a module casing 238.

FIG. 17 shows an example of a minimum arrangement circuit for implementing the present invention in the form of a converter. A combination of this minimum arrangement circuit enables formation of such a converter circuit as to satisfy the aforementioned effects. For example, a negative terminal in FIG. 17 is connected to a positive terminal of a second arrangement circuit to form a connection point, the connection point is used as an output terminal. Therefore, connection of both ends of the arrangement circuits connected in series to a power source enables formation of two-level inverter.

The circuit of FIG. 17 is a basic circuit of a converter circuit which includes a module having the prior art IGBT and the diode built therein and also includes an external circuit. In the prior art, when an external circuit is required, connection wiring is provided outside of the module. For example, when a capacitance or a resistance is connected in parallel to a switching element as in the first or second embodiment, the connection is provided by an external connection circuit of the module. This is because a Si recovery loss in the prior art is large.

In the present invention, a diode including a Schottky junction of a compound semiconductor is used as the diode. Thus the recovery loss of the present invention is remarkably reduced when compared with that of the Si PN-diode in the prior art. For this reason, capacitance and resistance components connected in parallel are accommodated in an identical module package so that the converter circuit satisfies non-resonance condition at the time moment of the diode recovery as shown by the relationship (1) and a basic circuit module is provided, thus forming a converter circuit which exhibits the aforementioned effects.

In the present invention, since the SBD of the compound semiconductor is used as the diode in place of the Si-PND in the prior art, a loss caused by the recovery of the diode can be sufficiently suppressed to a small level. For this reason, the present invention has a merit that the diode can be accommodated in the module of the minimum arrangement circuit to form a oscillation suppressing basic circuit as shown in FIG. 17. As a result, combined effects including reduction of the number of components in the converter circuit can be expected.

### 11. Eleventh Embodiment

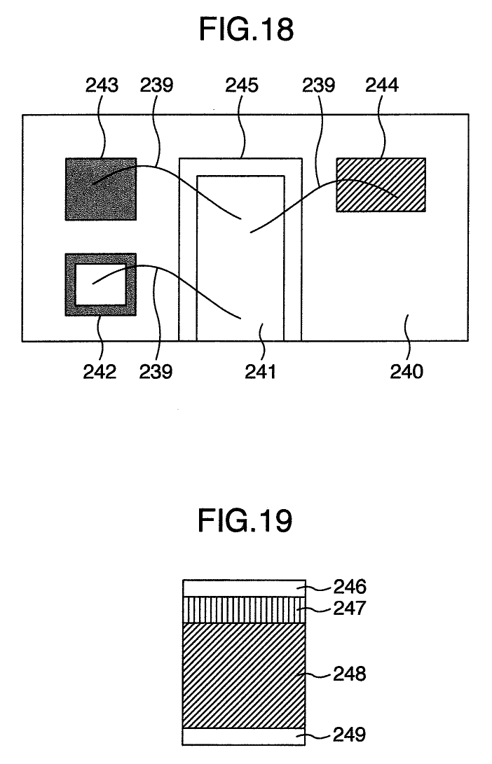

FIG. 18 shows an eleventh embodiment of the present invention. FIG. 18 shows an example of a chip array in the package having the arrangement of FIG. 17. The present embodiment is arranged so that the oscillation suppressing capacitance 233 and the oscillation suppressing resistance 234 in FIG. 17 are built in an identical chip. FIG. 18 shows a relationship between a substrate and elements forming the interior of the casing in FIG. 17. Shown in FIG. 18 are wire bonding lines 239, a substrate positive part 240, a substrate negative part 241, a switching element 242, a diode element 243, a oscillation suppressing circuit element 244, and an insulator 245. The present invention is applied to a converter circuit having a breakdown voltage of 200V or more. Thus, when a wiring pattern is previously formed on the surface of the substrate; the insulator 245 is provided on the rear surface of the substrate and also on the insulated substrate to be isolated from the substrate negative part 241; the switching element 242, the diode element 243, and the oscillation suppressing circuit element 244 are combined and mounted on the substrate; and then bonded with the wire bonding lines 239 as shown in FIG. 18, whereby such a circuit pattern as shown in FIG. 17 can be formed.

The present embodiment has been arranged to include one diode chip, one switching element chip, and one oscillation suppressing circuit chip. However, it is obvious that, even when a ratio between the PN junction surface area and the Schottky junction surface area is modified by changing chip arrangement so that current ratings of modules become the same, effects similar to the above embodiment can be obtained.

### 12. Twelfth Embodiment

FIG. 19 shows a twelfth embodiment of the present invention. FIG. 19 shows an example of a structure of the oscillation suppressing circuit element 244 in FIG. 18. In the present embodiment, the oscillation suppressing circuit element 244 in FIG. 18 is provided in the form of an identical chip, and a capacitor part and a resistance part are formed to be laminated between the front and back surfaces of the chip. FIG. 19 shows a relationship between the substrate and the elements in the casing. Shown in FIG. 19 are a surface electrode 246, a capacitor part 247, a resistance part 248, and a back surface electrode 249.

The capacitance and resistance components are formed in the same chip in this way to form a basic circuit. Since such a converter circuit as to meet the relationship (1) is formed by combining such basic circuits, such a converter circuit can be formed in a convenient and easy manner. Since a wiring area in the oscillation suppressing circuit is small, an inductance component in an impedance of the oscillation attenuating circuit element can be made small. As a result, there can be provided a circuit which has small variations in characteristic.

The internal element structure of the oscillation suppressing circuit is such a laminated structure as shown in FIG. 19. However, even when a chip having an element structure other than FIG. 19 is provided in order to form an optimum capacitance or resistance, it is obvious that the effects of the present invention can be sufficiently exhibited.

Although the embodiment of the present invention has been explained in connection of the example of the illustrated converter circuit as the 2-level inverter, the converter circuit of the present invention can be applied even to a multi-level inverter or converter having 3 or more voltage levels, or to another converter such as a DC-DC converter.

It should be further understood by those skilled in the art that the foregoing description has been made on embodiments of the invention and that various changes and modifications may be made in the invention without departing from the spirit of the invention and the scope of the appended claims.

1. A circuit device including a plurality of circuit elements,
said circuit elements comprising:
at least one switching element and at lease one diode arranged so as to be forwardly biased and conducted when the switching element is conducted,
wherein, with respect to an impedance of the circuit constants between positive and negative terminals, a relationship, R²>4Ls/C, with a capacitance C, a resistance R, and a wiring inductance Ls between the positive and negative terminals, is satisfied at the time moment when a backflow current of at least the diode becomes zero.

2. A circuit device according to claim 1, wherein the diode is made of a compound semiconductor.

3. A circuit device according to claim 1, wherein an electrode of the diode has a Schottky barrier.

4. A circuit device according to claim 1, wherein a relationship, Ron²>4Ls/Cj, with a junction capacitance Cj of the diode, an ON resistance Ron of the switching element, and a wiring inductance Ls, is satisfied at the time moment when the backflow current of at least the diode becomes zero.

5. A circuit device according to claim 1, wherein an inductance L is connected between a positive or negative terminal and the switching element, and the capacitance C and the resistance R connected in series with the capacitance C are connected in parallel to the diode.

6. A circuit device according to claim 5, wherein the circuit device has an integrated circuit element having the capacitance C and the resistance R built in an identical chip.

7. A circuit device according to claim 6, wherein the integrated circuit element has a rectification characteristic.

8. A circuit system as a combination of two of the first and second circuit devices set forth in claim 4, wherein said system has an output terminal, said output terminal is connected to a negative terminal of the first circuit device, and connected to a positive terminal of the second circuit device at an identical potential.

9. A converter circuit as a combination of the circuit system set forth in claim 8 and a power source of a voltage of 200V or more.

10. A power module having the switching element and the diode in the circuit device set forth in claim 1 built therein.

11. A converter which includes the circuit device set forth in claim 1 and which is connected with a circuit module having the capacitance C and the resistance R built in an identical chip.

12. A gate control device which includes the circuit device set forth in claim 1, and which reduces an oscillation current of an AC terminal by controlling a transient impedance when the switching element is turned ON or OFF.
